(19) United States
(12) Patent Application Publication
(10) Pub. No.: US 2024/0211210 A1
(43) Pub. Date: Jun. 27, 2024

(54) APPARATUS AND METHOD WITH IN-MEMORY COMPUTING

(71) Applicants: Samsung Electronics Co., Ltd., Suwon-si (KR); Research & Business Foundation SUNGKYUNKWAN UNIVERSITY, Suwon-si (KR)

(72) Inventors: Jaerok KIM, Suwon-si (KR); Yoonmyung LEE, Seongnam-si (KR)

(73) Assignees: Samsung Electronics Co., Ltd., Suwon-si (KR); Research & Business Foundation SUNGKYUNKWAN UNIVERSITY, Suwon-si (KR)

(21) Appl. No.: 18/331,310

(22) Filed: Jun. 8, 2023

(30) Foreign Application Priority Data
Dec. 27, 2022 (KR) 10-2022-0185331

(51) Int. Cl. G06F 7/544; G11C 11/418; G11C 11/419

(52) U.S. Cl. CPC G06F 7/5443; G11C 11/418; G11C 11/419

(57) ABSTRACT

An apparatus and method with in-memory computing (IMC) is provided. An apparatus includes a memory including rows; a self-timed circuit including sub-circuits corresponding to the respective rows, and operates asynchronously with a clock; and a control circuit configured to control the self-timed circuit. Based on input to a first sub-circuit being a first value, the first sub-circuit skips accessing a first row of memory, corresponding to the first sub-circuit and transfer a first output signal received from a first neighboring sub-circuit, to a second neighboring sub-circuit among the sub-circuits. Based on input to the first sub-circuit being a second value, the first sub-circuit accesses the first row of memory, performs an operator-based operation on the second value and weights stored in the first row, generates a second output signal based on the performed operation, and transfers the second output signal to the second neighboring sub-circuit.

### CROSS-REFERENCE TO RELATED APPLICATIONS

This application claims the benefit under 35 USC § 119(a) of Korean Patent Application No. 10-2022-0185331, filed on Dec. 27, 2022, in the Korean Intellectual Property Office, the entire disclosure of which is incorporated herein by reference for all purposes.

### BACKGROUND

### 1. Field

The following description relates to an apparatus and method with in-memory computing (IMC).

### 2. Description of Related Art

To increase the operation processing speed of a deep neural network (DNN) used in implementation of an artificial intelligence (AI) system, a multiplication operation of input data of “0” may not be performed because a result of the multiplication operation becomes “0” when the input data includes “0”.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a computing apparatus includes a memory comprising a plurality of rows; a self-timed circuit including a plurality of sub-circuits corresponding to the plurality of rows, respectively, and configured to operate asynchronously with a clock; and a control circuit configured to control the self-timed circuit, wherein, based on input to a first sub-circuit among the sub-circuits being a first value, the first sub-circuit is configured to skip accessing a first row of memory, corresponding to the first sub-circuit and transfer a first output signal received from a first neighboring sub-circuit among the sub-circuits, to a second neighboring sub-circuit among the sub-circuits, and wherein, based on to the first sub-circuit being a second value, the first sub-circuit is configured to access the first row of memory, perform an operator-based operation on the second value and weights stored in the first row, generate a second output signal based on the performed operation, and transfer the second output signal to the second neighboring sub-circuit.

The first sub-circuit may be configured to generate a word line driving signal and a pre-charge signal based on the first sub-circuit being the second value and receiving the first output signal from the first neighboring sub-circuit.

The operation may be performed on the second value and the weights of the row corresponding to the first sub-circuit by the word line driving signal.

The pre-charge signal may be generated in response to the operation on the second value and weights of the row corresponding to the first sub-circuit being completed.

In the computing apparatus, bit lines and bit line bars of the memory may be pre-charged for accessing a row corresponding to the second neighboring sub-circuit by the pre-charge signal.

The second output signal to be transferred to the second neighboring sub-circuit may be generated in response to the bit lines of the row corresponding to the second neighboring sub-circuit being pre-charged.

The computing apparatus may further include an accumulator configured to receive a predetermined number of bits in a result generated by performing the operation on the second value and the weights of the first row and accumulate the received bits and previous bits.

The accumulator may be configured to determine a counting direction of an up/down counter based on a most significant bit (MSB) of the received bits and a carry bit determined by a result generated by accumulating the received bits and the previous bits.

The accumulator may be configured to generate output bits based on the result generated by accumulating the received bits and the previous bits and the counting direction of the up/down counter.

The control circuit may be configured to control the self-timed circuit to access a row of the memory corresponding to the second neighboring sub-circuit to which a second value, is input by detecting the accumulating of the received bits and the previous bits by the accumulator.

In another general aspect, a computing apparatus includes a memory comprising a plurality of rows; a self-timed circuit including a plurality of sub-circuits corresponding to the plurality of rows of the memory, respectively, wherein, based on input to a first sub-circuit among the sub-circuits being a first value, the first sub-circuit is configured to skip accessing a first row of memory, corresponding to the first sub-circuit and transfer a first output signal received from a first neighboring sub-circuit among the sub-circuits, to a second neighboring sub-circuit among the sub-circuits, and wherein, based on input to the first sub-circuit being a second value, the first sub-circuit is configured to access the first row, perform an operator-based operation on the second value and weights stored in the first row, generate a second output signal based on the performed operation, and transfer the second output signal to the second neighboring sub-circuit; a control circuit configured to control the self-timed circuit; and an accumulator configured to receive a predetermined number of bits in a result generated by performing the operation on the second value and the weights of the first row and accumulate the received bits and previous bits.

In another general aspect, a method performed by a computing apparatus, the computing apparatus having a memory including a plurality of rows, a self-timed circuit configured to operate asynchronously with a clock and comprising sub-circuits corresponding to the respective rows of the memory, and a control circuit configured to control the self-timed circuit, the method includes skipping, in response to input to a first sub-circuit among the sub-circuits having a first value, accessing a first row corresponding to the first sub-circuit, and transferring a first output signal received from a first neighboring sub-circuit among the sub-circuits to a second neighboring sub-circuit among the sub-circuits; and in response to input to the second neighboring sub-circuit among the sub-circuits having a second value, accessing a row of memory corresponding to the second neighboring sub-circuit, performing an operator-based operation on the second value and weights stored in the row corresponding to the second neighboring sub-circuit, generating a second output signal based on the performed operation, and transferring the generated second output signal to a subsequent neighboring sub-circuit.

The second neighboring sub-circuit may be configured to generate a word line driving signal and a pre-charge signal based on input to the second neighboring sub-circuit being the second value and receiving the first output signal from the first sub-circuit.

The operation may be performed on the second value and the weights of the row corresponding to the second neighboring sub-circuit by the word line driving signal.

The pre-charge signal may be generated in response to the operation on the second value and the weights of the row corresponding to the second neighboring sub-circuit being completed.

The generating of the second output signal may include generating the second output signal in response to the bit lines of the row corresponding to the subsequent neighboring sub-circuit being pre-charged after accessing the row corresponding to the second neighboring sub-circuit.

The method may be performed using the accumulator configured to determine a counting direction of an up/down counter based on a most significant bit (MSB) of the received bits and a carry bit determined by a result generated by accumulating the received bits and the previous bits.

The method may be performed using the accumulator configured to generate output bits based on the result generated by accumulating the received bits and the previous bits and the counting direction of the up/down counter.

Other features and aspects will be apparent from the following detailed description, the drawings, and the claims.

### BRIEF DESCRIPTION OF THE DRAWINGS

FIG. 1 illustrates an example computing apparatus according to one or more embodiments.

FIG. 2 illustrates an example method with zero skipping according to one or more embodiments.

FIG. 3 illustrates an example operation of a self-timed circuit according to one or more embodiments.

FIG. 4 illustrates an example method with zero skipping according to one or more embodiments.

FIG. 5 illustrates an example hand-shake (HS) circuit of a sub-circuit according to one or more embodiments.

FIG. 6 illustrates an example timing diagram of signals for demonstrating an operation of a sub-circuit according to one or more embodiments.

FIG. 7 illustrates an example operation of an accumulator according to one or more embodiments.

FIG. 8 illustrates an example operation of an accumulator according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing. It is to be understood that if a component (e.g., a first component) is referred to, with or without the term “operatively” or “communicatively,” as “coupled with,” “coupled to,” “connected with,” or “connected to” another component (e.g., a second component), it means that the component may be coupled with the other component directly (e.g., by wire), wirelessly, or via a third component.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein.

As an in-memory operation of implementing input zero skipping during an in-memory processing, an input preprocessing process and peripheral circuits for the input preprocessing process may typically be necessary. In a typical input preprocessing process, the input data other than “0” has to be separately stored from an index thereof. Further, a typical zero skipping operation needs to be performed prior to the non-zero input data is provided to processing computer circuitry that performs multiply-and-accumulate (MAC) operations. As a result, the typical input preprocessing process is time consuming and also causes structural complexity due to extra circuitry areas needed for these typical extra peripheral circuits.

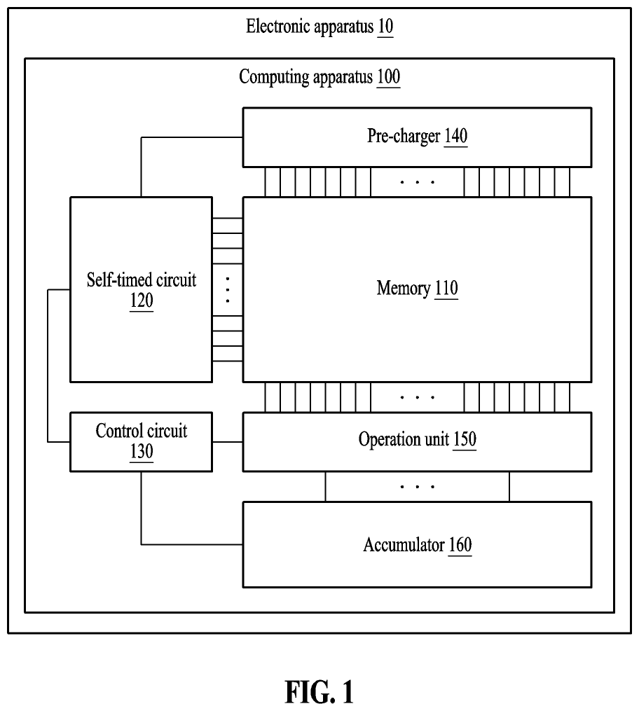

FIG. 1 illustrates an example computing apparatus according to one or more embodiments.

As shown in FIG. 1, an example computing apparatus 100 may be an in-memory computing (IMC) apparatus (or also referred to as an processor-in-memory (PIM) memory) including a memory 110 and a peripheral circuit for an IMC operation. The computing apparatus 100 may be configured to perform multiply-and-accumulate (MAC) operation processing of a deep neural network (DNN) and may be implemented as an accelerator circuit for the MAC operation processing.

An electronic apparatus 10 is representative of one or more processors configured to execute instructions stored in one or more memories, e.g., the memory 110. The execution of the instructions by the one or more processors may configure the one or more processors to control performance of any one or any combinations of operations/methods described herein with respect to the computing apparatus 100.

In a non-limiting example, the memory 110 may correspond to a six-transistor (6T) or eight-transistor (8T) static random access memory (SRAM) macro. Hereinafter, the memory 110 may include memory cells that may be arranged in a 64×64 array, though examples are not limited thereto.

In such an array configuration, a single row of the memory 110 may store eight pieces of weight data corresponding to “8” bits. 8-bit weight data may be stored in a two's complement format, as a non-limiting example. If each weight data is expressed as a decimal number, each weight data may have a value within a range of “−128” to “+127”, as a non-limiting example.

In a non-limiting example, the peripheral circuit of the computing apparatus 100 may include a self-timed circuit 120, a control circuit 130, a pre-charger (i.e., pre-charge circuit) 140, an operation unit (i.e., operation circuit) 150, and an accumulator 160.

The self-timed circuit 120 may be configured to operate asynchronously with a clock and may include sub-circuits corresponding to respective rows of the memory 110. For example, the sub-circuits of the self-timed circuit 120 may be respectively connected to each of the rows (e.g., “64” rows) of the memory 110. A sub-circuit may be representative of a hand-shaking (HS) block (or HS circuit block), or any other suitable circuit.

The pre-charger 140 and the operation unit 150 may be each connected to columns (e.g., “64” columns) of the memory 110. As a non-limiting example, in a reading and/or writing process of the memory 110 corresponding to an SRAM, the pre-charger 140 may be configured to previously charge (pre-charge) bit lines (BLs) and bit line bars (BLBs) corresponding to the columns of the memory 110. For example, the memory 110 may have a crossbar configuration. The operation unit 150 may include a column multiplexer (MUX), and a sense amplifier (SA) configured to read stored weight data by amplifying a voltage difference caused by data stored in a memory cell.

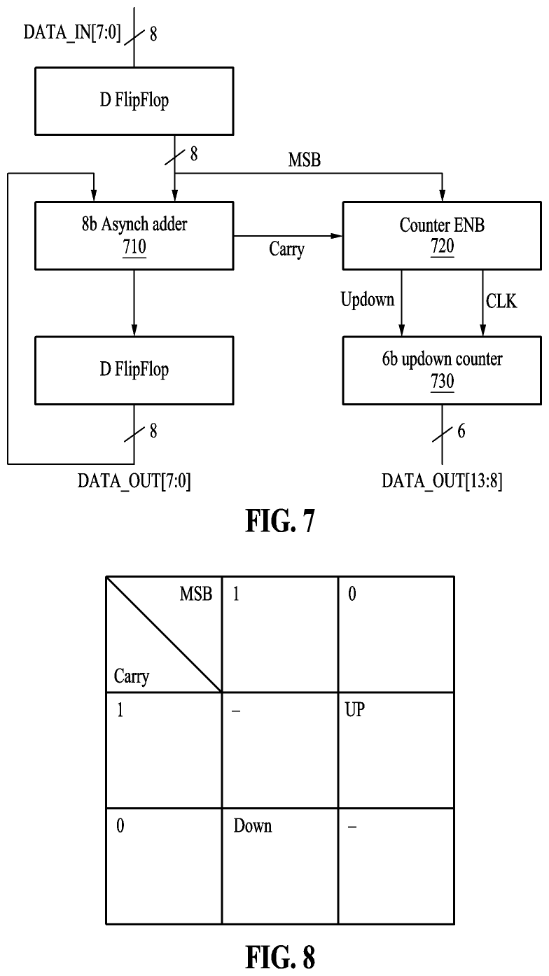

In a non-limiting example, the accumulator 160 may include 14-bit asynchronous accumulator circuits (e.g., eight 14-bit asynchronous accumulators). Each of the 14-bit asynchronous accumulator circuits may be configured to receive, as inputs, 8-bit operation results (or 8-bit data) for each row of the memory 110 from the operation unit 150, and accumulate or add an input bit and a previously input bit, to output 14-bit data. A computation operation of the accumulator 160 will be described below with reference to FIGS. 7 and 8.

The control circuit 130 may be representative of the one or more processors and configured to control the self-timed circuit 120 and the other circuits of the computing apparatus 100. In a non-limiting example, the control circuit 130 may configure/control the self-timed circuit 120 to access a next row of the memory 110 by detecting that the accumulator 160 has accumulated the input bit and the previously input bit.

Accessing a row of the memory 110 may include performing an operation on a corresponding row of the memory 110 in response to input feature data (or input activation) not being “0”.

If the input feature data is zero “0”, accessing a corresponding row of the memory 110 may be skipped, would have been a result of “0” as obtained through a multiplication operation. If the input feature data is “1”, a multiplication operation of a weight stored in a row of the memory 110 and the input feature data may correspond to an operation of reading the weight stored in the row of the memory 110.

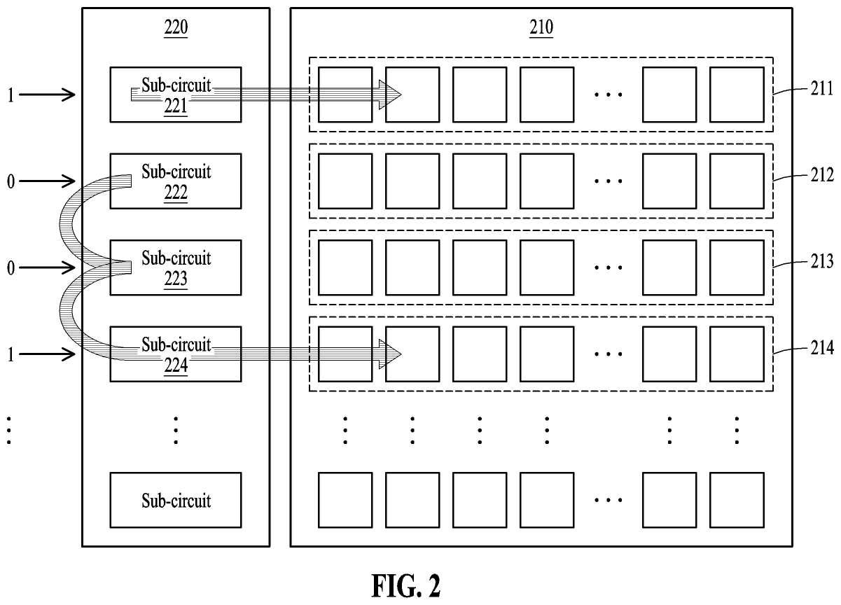

FIG. 2 illustrates an example method with zero skipping according to one or more embodiments.

A memory 210 (e.g., the memory 110 described above with reference to FIG. 1) may include, for example, “64” rows. Rows 211, 212, 213, and 214 may be rows of the memory 210 corresponding to index values of “0” through “3”. Each of the rows of the memory 210 may include, for example, “64” memory cells.

A self-timed circuit 220 (e.g., the self-timed circuit 120 described above with reference to FIG. 1) may include sub-circuits. The number of sub-circuits may be the same as the number of rows of the memory 210. In an example, the sub-circuits may be arranged orresponding to the rows of the memory 210, respectively. Sub-circuits 221, 222, 223, and 224 may respectively correspond to the rows of the memory 210 with the respective index values of “0” through “3”.

Referring to FIG. 2, the example method includes determining, based on input feature data, whether the self-timed circuit 220 skips accessing the memory 210. In an example, based on the input feature data, it is determined whether a corresponding sub-circuit of the self-timed circuit 220 accesses a corresponding row of the memory 210.

As shown in FIG. 2, since input feature data to the sub-circuit 221 is “1”, it is determined that the sub-circuit 221 may access the corresponding (or mateched) row 211, and thus may perform an operation (e.g., a multiplication operation) that is based on weights stored in the corresponding row 211 and the input feature data.

Since input feature data of the sub-circuit 222 is “0”, it is determined that the sub-circuit 222 may not read (i.e., skip accessing) the corresponding (or matched) row 212. Thus, the sub-circuit 222 may skip an operation that is based on the input feature data and weights stored in the corresponding row 212.

Since input feature data of the sub-circuit 223 is “0”, it is determined that the sub-circuit 223 may skip accessing the corresponding row 213. Thus, the sub-circuit 223 may skip an operation that is based on the input feature data and weights stored in the row 213.

Since input feature data of the sub-circuit 224 is “1”, it is determined that the sub-circuit 224 may access the corresponding row 214, and thus may perform an operation (e.g., a multiplication operation) that is based on weights stored in the row 214 and the input feature data.

In other words, the sub-circuit 221 may access the row 211 to perform a multiplication operation on the input feature data and the weights of the row 211, and resulting bits of the multiplication operation may be held in an accumulator (e.g., the accumulator 160 described above with reference to FIG. 1). The sub-circuits 222 and 223 may not access the respective rows 212 and 213, and respective operations of accessing the rows 212 and 213 may be thus skipped. The sub-circuit 224 may access the row 214 to perform a multiplication operation on the input feature data and the weights of the row 214. The accumulator may accumulate resulting bits and the held the resulting bits by reading the row 214.

The above operations may be performed on 8-bit weights included in each of the “64” rows of the memory 210 based on the input feature data.

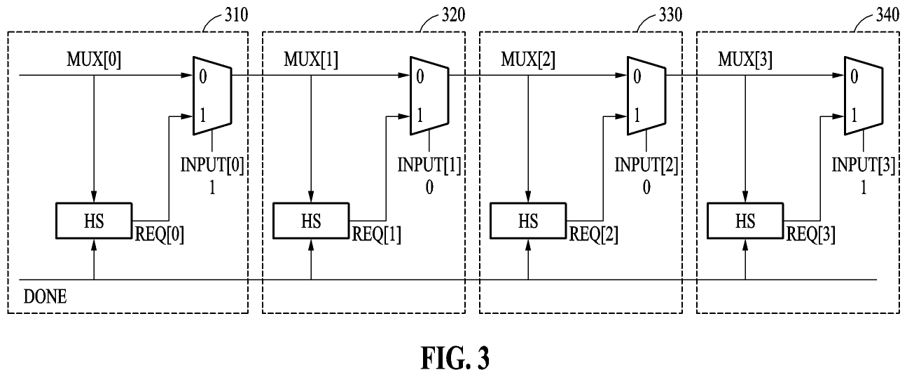

FIG. 3 illustrates an example operation of a self-timed circuit according to one or more embodiments.

The self-timed circuit (e.g., the self-timed circuit 120 of FIG. 1 or the self-timed circuit 220 of FIG. 2) may be configured to operate asynchronously with a clock, and may include sub-circuits corresponding to respective rows of a memory (e.g., the memory 110 of FIG. 1 or the memory 210 of FIG. 2).

Referring to FIG. 3, as a non-limiting example, the self-timed circuit may include sub-circuits 310, 320, 330, and 340. The sub-circuits 310, 320, 330, and 340 may be representative of the respective sub-circuits 221, 222, 223, and 224 of FIG. 2. For convenience of description, although four sub-circuits, e.g., the sub-circuits 310, 320, 330, and 340, are merely illustrated in FIG. 3, the number of sub-circuits in the self-timed circuit is not limited to four. The sub-circuits 310, 320, 330, and 340 may correspond to row[0], row[1], row[2], and row[3] (e.g., the rows 211 through 214 of FIG. 2) of the memory, respectively.

INPUT[0], INPUT[1], INPUT[2], and INPUT[3] may be representative of input feature data input to the sub-circuits 310, 320, 330, and 340, respectively.

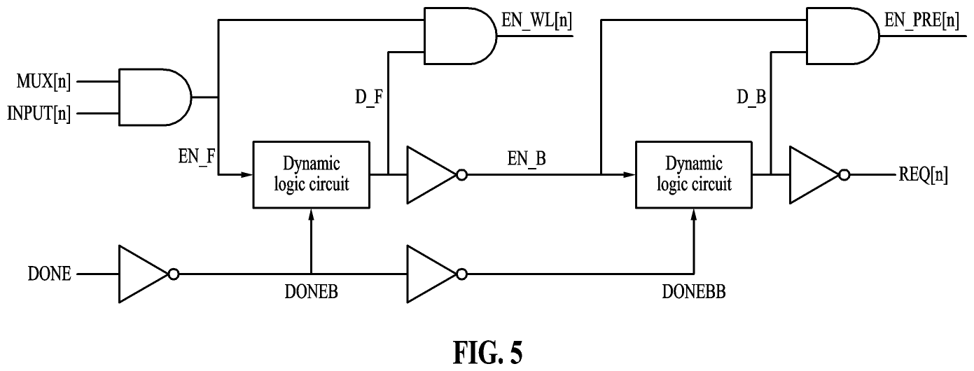

In the example of FIG. 3, the sub-circuits 310, 320, 330, and 340 may each include an HS circuit and a MUX. The HS circuit will be described with reference to FIG. 5 below.

A signal MUX[0] may be a start signal of an IMC operation. A control circuit (e.g., the control circuit 130 of FIG. 1) may control the self-timed circuit to start an operation by allowing the signal MUX[0] to be “1” (or a high signal).

If the sub-circuit 310 receives INPUT[0]=1 and the signal MUX[0] that is a high signal, an operation may be performed on INPUT[0]=1 and weights of the row[0] (e.g., the row 211 of FIG. 2). When the sub-circuit 310 accesses the row[0], the HS circuit of the sub-circuit 310 may generate a signal REQ[0] that is a high signal and that is to be transferred to the sub-circuit 320. The MUX of the sub-circuit 310 may transfer the signal REQ[0] to the sub-circuit 320 in response to INPUT[0]=1. The signal REQ[0] may correspond to a signal MUX[1] shown in FIG. 3.

If the sub-circuit 320 receives INPUT[1]=0 and receives the signal REQ[0] (i.e., the signal MUX[1]) from the sub-circuit 310, accessing the row[1] (e.g., the row 212 of FIG. 2) may be skipped. The HS circuit of the sub-circuit 320 may not generate a signal REQ[1] in response to INPUT[1]=0. The MUX of the sub-circuit 320 may transfer the signal MUX[1]to the sub-circuit 330 in response to INPUT[1]=0.

If the sub-circuit 330 receives INPUT[2]=0 and receives a signal MUX[2] (i.e., the signal MUX[1]) from the sub-circuit 320, accessing the row[2] (e.g., the row 213 of FIG. 2) may be skipped. The HS circuit of the sub-circuit 330 may not generate a signal REQ[2] in response to INPUT[1]=0. The MUX of the sub-circuit 330 may transfer the signal MUX[2] to the sub-circuit 340. The signal MUX[2] may be transferred as a signal MUX[3] to the sub-circuit 340.

If the sub-circuit 340 receives INPUT[3]=1 and receives the signal MUX[3] from the sub-circuit 330, an operation may be performed on INPUT[3]=1 and weights of the row[3] (e.g., the row 214 of FIG. 2). When the sub-circuit 340 accesses the row[3], the HS circuit of the sub-circuit 340 may generate a signal REQ[3] that is a high signal and that is to be transferred to a neighboring/next sub-circuit. The MUX of the sub-circuit 340 may transfer the signal REQ[3] to the neighboring/next sub-circuit.

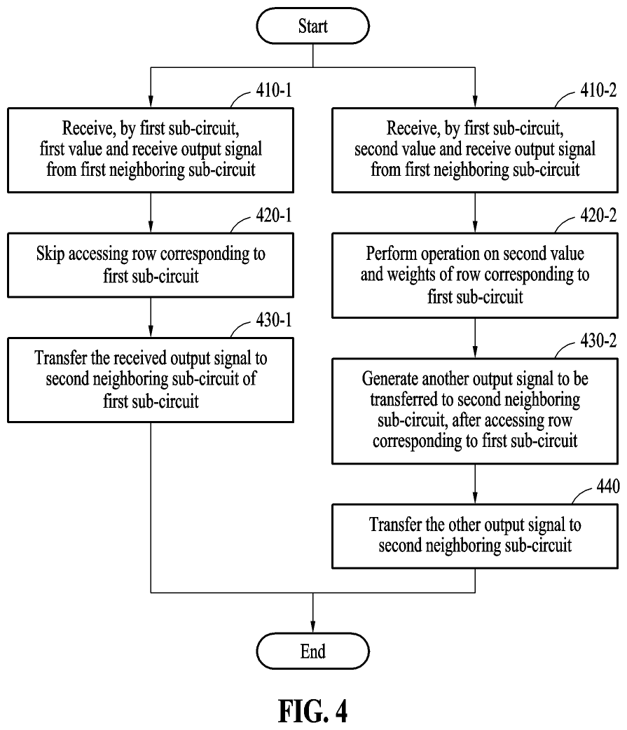

FIG. 4 illustrates an example method with zero skipping according to one or more embodiments.

Referring to an example flowchart illustrated in FIG. 4, the example method may include operations 410-1 through 440. These operations may be performed by a computing apparatus (e.g., the computing apparatus 100 described above with reference to FIG. 1).

Operations 410-1 and 410-2 may be performed depending on whether input feature data is “0” or “1”. Hereinafter, the input feature data may be referred to as INPUT.

In operation 410-1, a first sub-circuit may receive a first value as an input and receive an output signal from a first neighboring sub-circuit of the first sub-circuit. The first value may indicate INPUT=0. The first neighboring sub-circuit may correspond to a row of the memory having an index value that is less than that of the first sub-circuit by “1”. The output signal of the first neighboring sub-circuit may indicate a MUX signal as a high signal.

In operation 420-1, it is determined, based on a result of operation 410-1, that accessing a row corresponding to the first sub-circuit may be skipped. For example, in response to INPUT=0, the first sub-circuit may skip accessing the row corresponding to the first sub-circuit.

In operation 430-1, the received output signal may be transferred to a second neighboring sub-circuit of the first sub-circuit. The second neighboring sub-circuit may be a sub-circuit having an index value of a corresponding row of the memory which is greater than that of the first sub-circuit by “1”.

In operation 410-2, the first sub-circuit may receive a second value as an input and receive an output signal from the first neighboring sub-circuit. The second value may indicate INPUT=1.

In operation 420-2, it is determined, based on a result of operation 410-2, that an operation may be performed on the second value and weights of the row corresponding to the first sub-circuit.

In operation 430-2, after the row corresponding to the first sub-circuit is accessed, another output signal may be generated and transferred to the second neighboring sub-circuit. The other output signal may indicate a REQ signal as a high signal.

In operation 440, the generated other output signal may be transferred to the second neighboring sub-circuit. For example, the generated other output signal (or REQ signal) may be transferred as a MUX signal, as a high signal, to the second neighboring sub-circuit.

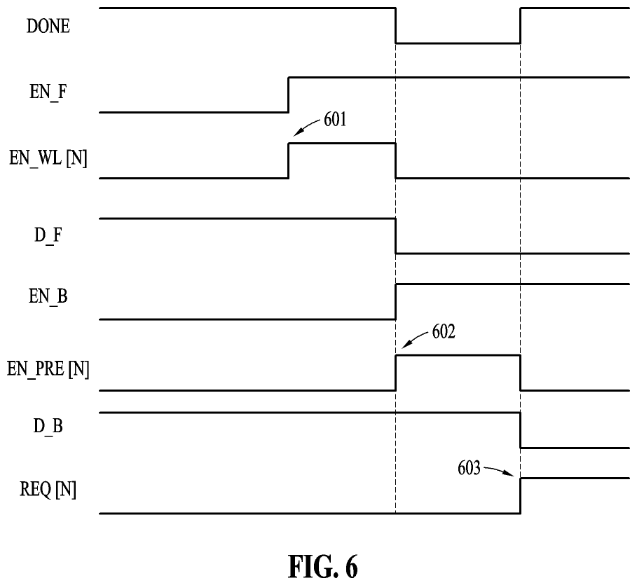

FIG. 5 illustrates an example hand-shake (HS) circuit of a sub-circuit and FIG. 6 illustrates an example timing diagram of signals for demonstrating an operation of a sub-circuit, according to one or more embodiments.

Referring to FIG. 5, an example HS circuit of a sub-circuit corresponds to a row[n] of a memory with an index value of “n” (n is an integer greater than or equal to “0”).

As a non-limiting example, INPUT[n] and signals MUX[n] and DONE may be input to the HS circuit of the sub-circuit, and signals EN_WL[n], EN_PRE[n], and REQ[n] may be output. INPUT[n] may be representative of input feature data corresponding to the row[n] of the memory with the index value of “n”. If n is “0”, MUX[0] may be representative of a start signal of an IMC operation. If n is greater than or equal to “1”, MUX[n] may be representative of REQ[n−1] or MUX[n−1]. If “INPUT[n−1]=1” is satisfied, a signal REQ[n−1], as a high signal, may allow MUX[n] to be a high signal. If “INPUT[n−1]=0” is satisfied, MUX[n−1], as a high signal, may allow MUX[n] to be a high signal.

If the sub-circuit receives INPUT[n]=1 as an input and receives MUX[n] that is a high signal, the signals EN_WL[n] and EN_PRE[n] may be generated.

EN_WL[n] may be representative of a word line driving signal of the row[n]. If EN_WL[n] is high, an operation (e.g., a multiplication operation) may be performed on input feature data and a weight of the row[n] by accessing the row[n]. A multiplication operation of INPUT=1 and the weight stored in the row[n] may correspond to an operation of reading the weight stored in the row[n].

EN_PRE[n] may be representative of a pre-charge signal of bit lines and bit line bars of the memory to access a row[n+1]. If the operation of the INPUT[n] and the weight of the row[n] is completed, EN_PRE[n] may become high. If EN_PRE[n] is high, columns of the memory may be pre-charged by a pre-charger (e.g., the pre-charger 140 described above with reference to FIG. 1).

The signal DONE may be representative of a signal for implementing a hand-shaking operation of the sub-circuit. If the operation (e.g., a multiplication operation) of reading the weight stored in the row[n] is completed, the signal DONE may become low. If pre-charging of the bit lines and bit line bars to access the row[n+1] is completed, the signal DONE may become high.

The sub-circuit may include a dynamic logic circuit. If DONEB (or DONEBB) input to the dynamic logic circuit is high and if EN_F (or EN_B) is high, an output may become low. If DONEB (or DONEBB) input to the dynamic logic circuit is low, an output may become high. Referring to FIG. 6, D_F may be representative of an output of the dynamic logic circuit in response to an input of DONEB, and D_B may be representative of an output of the dynamic logic circuit in response to an input of DONEBB.

Referring to FIG. 6, an example timing diagram of signals demonstrates an operation of the sub-circuit.

Since the signal DONEB generated/obtained by inverting the signal DONE is low, D_F, the output of the dynamic logic circuit, may be high. If INPUT[n]=1 is received as an input and if MUX[n] is high, EN_F may become high. Accordingly, at a time point 601, EN_WL, which is a product of EN_F and D_F, may also become high.

During a time period in which EN_WL[n] is high, an operation (e.g., a multiplication operation) may be performed on the input feature data and the weight of the row[n] by accessing the row[n]. A multiplication operation of INPUT=1 and the weight stored in the row[n] may correspond to an operation of reading the weight stored in the row[n].

If the operation of reading the weight stored in the row[n] is completed, the signal DONE may become low. Accordingly, D_F may become low, and EN_B generated/obtained by inverting D_F may become high. EN_WL[n] may become low. Since the signal DONEBB is low, D_B, the output of the dynamic logic circuit, may remain high. Accordingly, at a time point 602, EN_PRE[n], which is a product of EN_B and D_B, may also become high.

During a time period in which EN_PRE[n] is high, bit lines and bit line bars may be pre-charged to access a row[n+1].

If the pre-charging is completed, the signal DONE may become high. Accordingly, D_B and EN_PRE[n] may become low, and the signal REQ generated/obtained by inverting D_B may become high at a time point 603.

Unlike the example shown in FIG. 6, a delay may occur between the time points, during which signals may become high or low as a non-limiting example.

FIGS. 7 and 8 illustrate examples of an operation of an accumulator according to one or more embodiments.

As shown in FIG. 7, an example accumulator is demonstrated performing an accumulation operation of a 14-bit asynchronous accumulator circuit as a non-limiting example.

The example accumulator (e.g., the accumulator 160 described above with reference to FIG. 1) may include 14-bit asynchronous accumulator circuits. Each of the 14-bit asynchronous accumulator circuits may receive 8-bit operation results (or 8-bit data) for each row of a memory (e.g., the memory 110 described above with reference to FIG. 1 or the memory 210 described above with reference to FIG. 2) as inputs, and may accumulate (e.g., add) input bits and previously input bits, to generate and output 14-bit data.

Referring to FIG. 7, as a non-limiting example, a 14-bit asynchronous accumulator circuit may include D flip-flops that hold input and added 8-bit data, an 8-bit asynchronous adder 710, a counter enable ENB 720, and a 6-bit up/down counter 730.

The 8-bit asynchronous adder 710 may add input “8” bits and previous “8” bits. A result output from the 8-bit asynchronous adder 710 may be held in a D flip-flop and may be accumulated with 8 bits that are input subsequently.

The counter enable ENB 720 may determine a counting direction of the 6-bit up/down counter 730 based on a most significant bit (MSB) of the “8” bits input to the 8-bit asynchronous adder 710 and a carry bit determined by a result of accumulating the input “8” bits and the previous “8” bits.

8-bit weight data may be stored in a two's complement format in the memory. If the MSB of the “8” bits input to the 8-bit asynchronous adder 710 is “1” under consideration of a sign extension, 111111(2) may be representative of −1(10), and if the MSB is “0”, 000000(2) may be representative of 0(10). If the MSB is “1” and if the carry bit determined by the result of accumulating the input “8” bits and the previous “8” bits is “0”, “−1+0=−1” may be satisfied, and accordingly the counter enable ENB 720 may transmit a clock signal and a count-down signal to the 6-bit up/down counter 730. If the MSB is “0” and the carry bit determined by the result of accumulating the input “8” bits and the previous “8” bits is “1”, “0+1=1” may be satisfied, and accordingly the counter enable ENB 720 may transmit a clock signal and a count-up signal to the 6-bit up/down counter 730.

The 6-bit up/down counter 730 may operate for each clock signal and may determine upper “6” bits of a 14-bit output of the 14-bit asynchronous accumulator circuit based on the count-up signal and/or count-down signal (or a counting direction).

Referring to FIG. 8, if the MSB is “1” and if the carry bit determined by the above-described accumulation is “1”, then “−1+1=0” may be satisfied, and accordingly the counter enable ENB 720 may not generate a clock signal. If the MSB is “0” and the carry bit determined by the accumulation is “0”, then “0+0=0” may be satisfied, and accordingly the counter enable ENB 720 may not generate a clock signal. Only when the MSB is “1” and the carry bit determined by the accumulation is “0”, or when the MSB is “0” and the carry bit determined by the accumulation is “1”, then the counter enable 720 may generate a clock signal and the counting direction of the 6-bit up/down counter 730 may change. Thus, with such an example configuration, overhead of an accumulation operation may be significantly reduced.

The 14-bit asynchronous accumulator circuit may generate 14-bit output bits based on the result of accumulating the input “8” bits and the previous “8” bits and the counting direction of the 6-bit up/down counter 730.

A control circuit (e.g., the control circuit 130 of FIG. 1) may control a self-timed circuit (e.g., the self-timed circuit 120 described above with reference to FIG. 1) to access a next row of the memory by detecting that the 14-bit asynchronous accumulator circuit has accumulated the input “8” bits and the previous “8” bits.

The accumulation operation of the 14-bit asynchronous accumulator circuit described with reference to FIGS. 7 and 8 may be performed while bit lines and bit line bars are being pre-charged to access a next row when an operation of input feature data and a weight of an arbitrary row of the memory is completed. An operation (e.g., a multiplication operation) and an accumulation may be performed in a pipelining manner as a non-limiting example.

In an example, when weight data corresponding to “4” bits is stored in each row of the memory, the accumulator may include a 10-bit asynchronous accumulator circuit. Each 10-bit asynchronous accumulator circuit may include a 4-bit asynchronous adder, and a 6-bit up/down counter.

The processors, memories, computing apparatuses, electronic devices, circuits, units, adders, counters, and other apparatuses, devices, and components described herein with respect to FIGS. 1-8 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-8 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A computing apparatus, comprising:
a memory comprising a plurality of rows;
a self-timed circuit comprising a plurality of sub-circuits corresponding to the plurality of rows, respectively, and configured to operate asynchronously with a clock; and
a control circuit configured to control the self-timed circuit,
wherein, based on input to a first sub-circuit among the sub-circuits being a first value, the first sub-circuit is configured to skip accessing a first row of memory, corresponding to the first sub-circuit and transfer a first output signal received from a first neighboring sub-circuit among the sub-circuits, to a second neighboring sub-circuit among the sub-circuits, and
wherein, based on input to the first sub-circuit being a second value, the first sub-circuit is configured to access the first row of memory, perform an operator-based operation on the second value and weights stored in the first row, generate a second output signal based on the performed operation, and transfer the second output signal to the second neighboring sub-circuit.

2. The computing apparatus of claim 1, wherein the first sub-circuit is configured to generate a word line driving signal and a pre-charge signal based on input to the first sub-circuit being the second value and receiving the first output signal from the first neighboring sub-circuit.

3. The computing apparatus of claim 2, wherein the operation is performed on the second value and the weights of the row corresponding to the first sub-circuit by the word line driving signal.

4. The computing apparatus of claim 2, wherein the pre-charge signal is generated in response to the operation on the second value and weights of the row corresponding to the first sub-circuit being completed.

5. The computing apparatus of claim 2, wherein bit lines and bit line bars of the memory are pre-charged for accessing a row corresponding to the second neighboring sub-circuit by the pre-charge signal.

6. The computing apparatus of claim 5, wherein the second output signal to be transferred to the second neighboring sub-circuit is generated in response to the bit lines of the row corresponding to the second neighboring sub-circuit being pre-charged.

7. The computing apparatus of claim 1, further comprising:
an accumulator configured to receive a predetermined number of bits in a result generated by performing the operation on the second value and the weights of the first row and accumulate the received bits and previous bits.

8. The computing apparatus of claim 7, wherein the accumulator is configured to determine a counting direction of an up/down counter based on a most significant bit (MSB) of the received bits and a carry bit determined by a result generated by accumulating the received bits and the previous bits.

9. The computing apparatus of claim 8, wherein the accumulator is configured to generate output bits based on the result generated by accumulating the received bits and the previous bits and the counting direction of the up/down counter.

10. The computing apparatus of claim 7, wherein the control circuit is configured to control the self-timed circuit to access a row of the memory corresponding to the second neighboring sub-circuit to which a second value is input by detecting the accumulating of the received bits and the previous bits by the accumulator.

11. A computing apparatus, comprising:
a memory comprising a plurality of rows;
a self-timed circuit comprising a plurality of sub-circuits corresponding to the plurality of rows of the memory, respectively,
wherein, based on input to a first sub-circuit among the sub-circuits being a first value, the first sub-circuit is configured to skip accessing a first row of memory, corresponding to the first sub-circuit and transfer a first output signal received from a first neighboring sub-circuit among the sub-circuits, to a second neighboring sub-circuit among the sub-circuits, and
wherein, based on input to the first sub-circuit being a second value, the first sub-circuit is configured to access the first row, perform an operator-based operation on the second value and weights stored in the first row, generate a second output signal based on the performed operation, and transfer the second output signal to the second neighboring sub-circuit;
a control circuit configured to control the self-timed circuit; and
an accumulator configured to receive a predetermined number of bits in a result generated by performing the operation on the second value and the weights of the first row and accumulate the received bits and previous bits.

12. A method performed by a computing apparatus, the computing apparatus having a memory including a plurality of rows, a self-timed circuit configured to operate asynchronously with a clock and comprising sub-circuits corresponding to the respective rows of the memory, and a control circuit configured to control the self-timed circuit, the method comprising:
skipping, in response to input to a first sub-circuit among the sub-circuits having a first value, accessing a first row corresponding to the first sub-circuit, and transferring a first output signal received from a first neighboring sub-circuit among the sub-circuits to a second neighboring sub-circuit among the sub-circuits; and,
in response to input to the second neighboring sub-circuit among the sub-circuits having a second value, accessing a row of memory corresponding to the second neighboring sub-circuit, performing an operator-based operation on the second value and weights stored in the row corresponding to the second neighboring sub-circuit, generating a second output signal based on the performed operation, and transferring the generated second output signal to a subsequent neighboring sub-circuit.

13. The method of claim 12, wherein the second neighboring sub-circuit is configured to generate a word line driving signal and a pre-charge signal based on input to the second neighboring sub-circuit being the second value and receiving the first output signal from the first sub-circuit.

14. The method of claim 13, wherein the operation is performed on the second value and the weights of the row corresponding to the second neighboring sub-circuit by the word line driving signal.

15. The method of claim 13, wherein the pre-charge signal is generated in response to the operation on the second value and the weights of the row corresponding to the second neighboring sub-circuit being completed.

16. The method of claim 13, wherein bit lines and bit line bars of the memory are pre-charged for accessing a row corresponding to the subsequent neighboring sub-circuit by the pre-charge signal.

17. The method of claim 16, wherein the generating of the second output signal comprises generating the second output signal in response to the bit lines of the row corresponding to the subsequent neighboring sub-circuit being pre-charged after accessing the row corresponding to the second neighboring sub-circuit.

18. The method of claim 12, wherein the method is performed by the computing apparatus further comprises:
an accumulator configured to receive a predetermined number of bits in a result generated by performing the operation on the second value and the weights of the row corresponding to the second neighboring sub-circuit and accumulate the received bits and previous bits.

19. The method of claim 18, wherein the method is performed using the accumulator configured to determine a counting direction of an up/down counter based on a most significant bit (MSB) of the received bits and a carry bit determined by a result generated by accumulating the received bits and the previous bits.

20. The method of claim 19, wherein the method is performed using the accumulator configured to generate output bits based on the result generated by accumulating the received bits and the previous bits and the counting direction of the up/down counter.
